(19) United States
(12) Patent Application Publication
(10) Pub. No.: US 2026/0279464 A1
(43) Pub. Date: Sep. 17, 2026

(54) METHODS FOR OPERATING A NON-VOLATILE MEMORY ARRAY AND A NON-VOLATILE MEMORY CELL FOR IMPROVING WRITING EFFICIENCY AND ERASING EFFICIENCY

(71) Applicant: YIELD MICROELECTRONICS CORP., HSINCHU COUNTY (TW)

(72) Inventors: YU-TING HUANG, HSIN-CHU COUNTY (TW); CHI-PEI WU, HSIN-CHU COUNTY (TW)

(21) Appl. No.: 19/243,087

(22) Filed: Jun. 19, 2025

(30) Foreign Application Priority Data
Mar. 13, 2025 (TW) 114109330

(51) Int. Cl. G11C 16/30; G11C 16/08; G11C 16/24

(52) U.S. Cl. CPC G11C 16/30; G11C 16/08; G11C 16/24

(57) ABSTRACT

Methods for operating a non-volatile memory array and a non-volatile memory cell are disclosed. The non-volatile memory cell, coupled to a word line, a bit line, and a common-source line, includes an N-type FET having a threshold voltage. In a writing activity, the bit voltage of the bit line is a high voltage, the word voltage of the word line increases incrementally in response to the threshold voltage that increases incrementally, and the common-source voltage of the common-source line decreases incrementally in response to the threshold voltage that increases incrementally. In the erasing activity, the bit voltage is equal to a high voltage, the word voltage decreases incrementally in response to the threshold voltage that decreases incrementally, and the common-source voltage is equal to a grounding voltage.

### BACKGROUND OF THE INVENTION

This application claims priority for the TW patent application no. 114109330 filed on 13 Mar. 2025, the content of which is incorporated by reference in its entirely.

### FIELD OF THE INVENTION

The present invention relates to a method for operating a memory, particularly to methods for operating a non-volatile memory array and a non-volatile memory cell.

DESCRIPTION OF THE RELATED ART

THE Complementary Metal Oxide Semiconductor (CMOS) technology has been developed as a commonly used process for fabricating Application Specific Integrated Circuits (ASIC). Nowadays, as the computer information products are blooming, flash memories and Electrically Erasable Programmable Read Only Memory (EEPROM) have been widely used in electronic products since the data stored within will not volatilize but can be erased and programmed electrically. In addition, the data will not disappear even after the power is turned off.

Non-volatile memories are programmable and are able to adjust gate voltages of their transistors by storing charges, or to preserve the original gate voltages of transistors by not storing charges. When regarding to erase a non-volatile memory, the charges stored in the non-volatile memory are removed to resume the initial state of the memory, and return to its original gate voltages of the transistors. When a non-volatile memory performs a writing activity or an erasing voltage, the threshold voltage of the FET of the non-volatile memory changes. This is because the number of charges on the gate of the FET changes. When the threshold voltage changes, the voltage of the word line remains unchanged, which will prolong the time of the writing activity or the erasing activity and reduce the writing efficiency or erasing efficiency.

To overcome the abovementioned problems, the present invention provides methods for operating a non-volatile memory array and a non-volatile memory cell, so as to solve the afore-mentioned problems of the prior art.

### SUMMARY OF THE INVENTION

The present invention provides methods for operating a non-volatile memory array and a non-volatile memory cell, which shorten the time of a writing activity or an erasing activity to improve the writing efficiency or the erasing efficiency.

In an embodiment of the present invention, a method for operating a non-volatile memory array is provided. The non-volatile memory array includes a plurality of common-source lines arranged in parallel, a plurality of word lines arranged in parallel, a plurality of bit lines arranged in parallel, and a plurality of sub-memory arrays. The common-source lines include a first common-source line. The common-source lines are parallel to the word lines. The word lines include a first word line. The word lines are perpendicular to the bit lines. The bit lines include a first bit line, a second bit line, a third bit line, and a fourth bit line. Each of the sub-memory arrays is coupled to one of the common-source lines, one of the word lines, and four of the bit lines. Each of the sub-memory arrays includes a first non-volatile memory cell, a second non-volatile memory cell, a third non-volatile memory cell, and a fourth non-volatile memory cell. The first non-volatile memory cell is coupled to the first word line, the first bit line, and the first common-source line. The second non-volatile memory cell is coupled to the first word line, the second bit line, and the first common-source line. The third non-volatile memory cell is coupled to the first word line, the third bit line, and the first common-source line. The fourth non-volatile memory cell is coupled to the first word line, the fourth bit line, and the first common-source line. Each of the first non-volatile memory cell, the second non-volatile memory cell, the third non-volatile memory cell, and the fourth non-volatile memory cell includes an N-type field-effect transistor (FET). The first non-volatile memory cell, the second non-volatile memory cell, the third non-volatile memory cell, or the fourth non-volatile memory cell is used as an operable memory cell. The method includes:
applying a grounding voltage to the body of the N-type FET of the operable memory cell; and
when the operable memory cell performs a writing activity or an erasing activity, respectively applying a bit voltage, a first word voltage, and a first common-source voltage to the bit line, the first word line, and the first common-source line that are coupled to the operable memory cell;
wherein the N-type FET of the operable memory cell has a threshold voltage;
wherein in the writing activity, the bit voltage is equal to a high voltage, the first word voltage increases incrementally in response to the threshold voltage that increases incrementally, and the first common-source voltage decreases incrementally in response to the threshold voltage that increases incrementally;
wherein in the erasing activity, the bit voltage is equal to the high voltage, the first word voltage decreases incrementally in response to the threshold voltage that decreases incrementally, and the first common-source voltage is equal to the grounding voltage;
wherein the high voltage is equal to the drain-to-source breakdown voltage of the N-type FET of the operable memory cell minus the threshold voltage.

In an embodiment of the present invention, in the writing activity, the first word voltage is a low voltage, a middle voltage, or the high voltage, the first common-source voltage is the middle voltage, the low voltage, or the grounding voltage, the high voltage is greater than the middle voltage, the middle voltage is greater than the low voltage, and the low voltage is greater than the grounding voltage.

In an embodiment of the present invention, in the erasing activity, the first word voltage is a low voltage or the grounding voltage, the high voltage is greater than the low voltage, and the low voltage is greater than the grounding voltage.

In an embodiment of the present invention, when the operable memory cell does not perform the writing activity or the erasing activity, the bit line coupled to the operable memory cell is electrically floating, a second word voltage and a second common-source voltage are respectively applied to the first word line and the first common-source line, the second word voltage is the grounding voltage or a low voltage, the second common-source voltage is a middle voltage, the high voltage is greater than the middle voltage, the middle voltage is greater than the low voltage, and the low voltage is greater than the grounding voltage.

In an embodiment of the present invention, the body is implemented with a P-type well, a P-type semiconductor substrate, or a P-type epitaxial layer.

In an embodiment of the present invention, a method for operating a non-volatile memory cell that is coupled to a word line, a bit line, and a common-source line is provided. The non-volatile memory cell includes an N-type field-effect transistor (FET). The method includes:
applying a grounding voltage to the body of the N-type FET of the non-volatile memory cell; and
when the non-volatile memory cell performs a writing activity or an erasing activity, respectively applying a bit voltage, a first word voltage, and a first common-source voltage to the bit line, the word line, and the common-source line;
wherein the N-type FET of the non-volatile memory cell has a threshold voltage;
wherein in the writing activity, the bit voltage is equal to a high voltage, the first word voltage increases incrementally in response to the threshold voltage that increases incrementally, and the first common-source voltage decreases incrementally in response to the threshold voltage that increases incrementally;
wherein in the erasing activity, the bit voltage is equal to the high voltage, the first word voltage decreases incrementally in response to the threshold voltage that decreases incrementally, and the first common-source voltage is equal to the grounding voltage;
wherein the high voltage is equal to the drain-to-source breakdown voltage of the N-type FET of the non-volatile memory cell minus the threshold voltage.

In an embodiment of the present invention, in the writing activity, the first word voltage is a low voltage, a middle voltage, or the high voltage, the first common-source voltage is the middle voltage, the low voltage, or the grounding voltage, the high voltage is greater than the middle voltage, the middle voltage is greater than the low voltage, and the low voltage is greater than the grounding voltage.

In an embodiment of the present invention, in the erasing activity, the first word voltage is a low voltage or the grounding voltage, the high voltage is greater than the low voltage, and the low voltage is greater than the grounding voltage.

In an embodiment of the present invention, when the non-volatile memory cell does not perform the writing activity or the erasing activity, the bit line is electrically floating, a second word voltage and a second common-source voltage are respectively applied to the word line and the common-source line, the second word voltage is the grounding voltage or a low voltage, the second common-source voltage is a middle voltage, the high voltage is greater than the middle voltage, the middle voltage is greater than the low voltage, and the low voltage is greater than the grounding voltage.

In an embodiment of the present invention, the body is implemented with a P-type well, a P-type semiconductor substrate, or a P-type epitaxial layer.

To sum up, the methods for operating a non-volatile memory array and a non-volatile memory cell apply step voltages to the word line and the common-source line in the writing activity and apply a step voltage to the word line in the erasing activity to shorten the time of the writing activity or the erasing activity, thereby improving the writing efficiency or the erasing efficiency.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating a non-volatile memory array according to an embodiment of the present invention; and

FIG. 2 is a schematic diagram illustrating a non-volatile memory cell according to an embodiment of the present invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express what the embodiment in the present invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

Certain terms are used throughout the description and the claims to refer to particular components. One skilled in the art appreciates that a component may be referred to using different names. This disclosure does not intend to distinguish between components that differ in name but in function. In the description and in the claims, the term “comprise” is used in an open-ended fashion, and thus should be interpreted to mean “include, but not limited to.” The phrases “be coupled to,” “couples to,” and “coupling to” are intended to encompass any indirect or direct connection. Accordingly, if this disclosure mentions that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

In the following description, methods for operating a non-volatile memory array and a non-volatile memory cell will be provided. The methods apply step voltages to a word line and a common-source line in a writing activity and apply a step voltage to the word line in an erasing activity to shorten the time of the writing activity or the erasing activity, thereby improving the writing efficiency or the erasing efficiency.

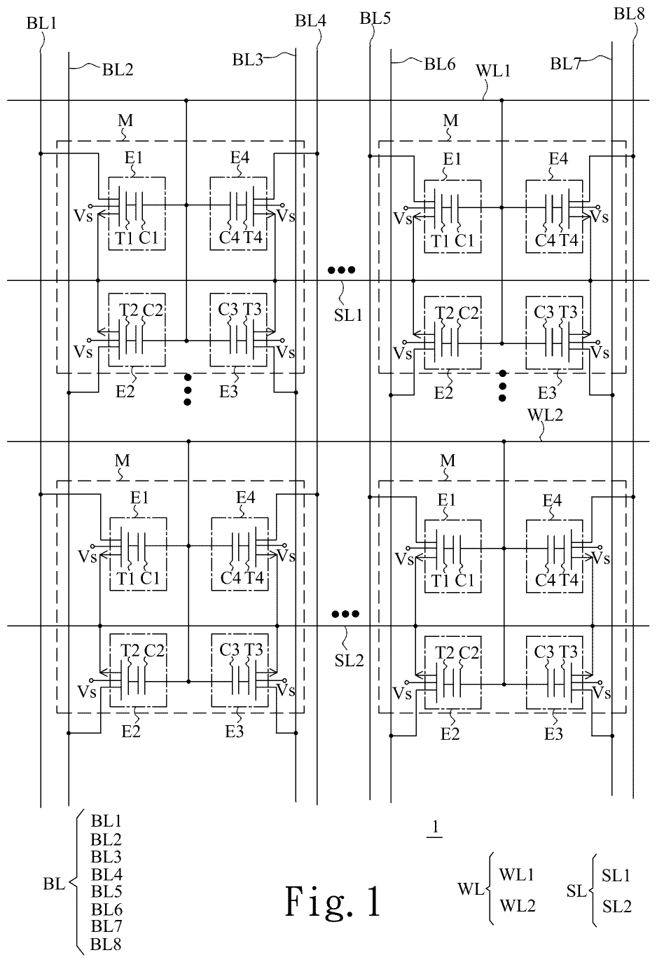

FIG. 1 is a schematic diagram illustrating a non-volatile memory array according to an embodiment of the present invention. Referring to FIG. 1, a method for operating a non-volatile memory array 1 of the present invention is introduced as follows. The non-volatile memory array 1 includes a plurality of common-source lines SL arranged in parallel, a plurality of word lines WL arranged in parallel, a plurality of bit lines BL arranged in parallel, and a plurality of sub-memory arrays M. The common-source lines SL include a first common-source line SL1 and a second common-source line SL2. The word lines WL are parallel to the common-source lines SL. The word lines WL include a first word line WL1 and a second word line WL2. The bit lines BL are perpendicular to the word lines WL. The bit lines BL include a first bit line BL1, a second bit line BL2, a third bit line BL3, a fourth bit line BL4, a fifth bit line BL5, a sixth bit line BL6, a seventh bit line BL7, and an eighth bit line BL8. Each sub-memory array M is coupled to one common-source line SL, one word line WL, and four bit lines BL. Each sub-memory array M includes a first non-volatile memory cell E1, a second non-volatile memory cell E2, a third non-volatile memory cell E3, and a fourth non-volatile memory cell E4. The first non-volatile memory cell E1 is coupled to the first word line WL1, the first bit line BL1, and the first common-source line SL1. The second non-volatile memory cell E2 is coupled to the first word line WL1, the second bit line BL2, and the first common-source line SL1. The third non-volatile memory cell E3 is coupled to the first word line WL1, the third bit line BL3, and the first common-source line SL1. The fourth non-volatile memory cell E4 is coupled to the first word line WL1, the fourth bit line BL4, and the first common-source line SL1. The first non-volatile memory cell E1, the second non-volatile memory cell E2, the third non-volatile memory cell E3, and the fourth non-volatile memory cell E4 respectively include N-type field-effect transistors (FETs) T1, T2, T3, and T4. The first non-volatile memory cell E1, the second non-volatile memory cell E2, the third non-volatile memory cell E3, or the fourth non-volatile memory cell E4 is used as an operable memory cell. The first non-volatile memory cell E1, the second non-volatile memory cell E2, the third non-volatile memory cell E3, and the fourth non-volatile memory cell E4 respectively further include capacitors C1, C2, C3, and C4.

Specifically, the gates of the N-type FETs T1, T2, T3, and T4 are respectively coupled to the first word line WL1 through the capacitors C1, C2, C3, and C4. The sources of the N-type FETs T1, T2, T3, and T4 are coupled to the first common-source line SL1. The drains of the N-type FETs T1, T2, T3, and T4 are respectively coupled to the first bit line BL1, the second bit line BL2, the third bit line BL3, and the fourth bit line BL4.

In the method for operating the non-volatile memory array 1, a grounding voltage as a body voltage Vs is applied to the body of the N-type FET T1, T2, T3, or T4 of the operable memory cell. The body is implemented with a P-type well, a P-type semiconductor substrate, or a P-type epitaxial layer. When the operable memory cell performs a writing activity or an erasing activity, a bit voltage, a first word voltage, and a first common-source voltage are respectively applied to the bit line BL, the first word line WL1, and the first common-source line SL1 that are coupled to the operable memory cell. The N-type FET T1, T2, T3, or T4 of the operable memory cell has a threshold voltage. In the writing activity, the bit voltage is equal to a high voltage, the first word voltage increases incrementally and serves as a step voltage in response to the threshold voltage that increases incrementally, and the first common-source voltage decreases incrementally and serves as a step voltage in response to the threshold voltage that increases incrementally. In the erasing activity, the bit voltage is equal to the high voltage, the first word voltage decreases incrementally and serves as a step voltage in response to the threshold voltage that decreases incrementally, and the first common-source voltage is equal to the grounding voltage. The high voltage is equal to the drain-to-source breakdown voltage of the N-type FET T1, T2, T3, or T4 of the operable memory cell minus the threshold voltage. The grounding voltage is zero voltage.

For example, in the writing activity, the first word voltage is a low voltage, a middle voltage, or the high voltage, the first common-source voltage is the middle voltage, the low voltage, or the grounding voltage. The high voltage is greater than the middle voltage, the middle voltage is greater than the low voltage, and the low voltage is greater than the grounding voltage. The middle voltage may be equal to the drain-to-source breakdown voltage of the N-type FET T1, T2, T3, or T4 of the operable memory cell×0.5. The low voltage may be equal to the drain-to-source breakdown voltage of the N-type FET T1, T2, T3, or T4 of the operable memory cell×0.25. In the erasing activity, the first word voltage is the low voltage or the grounding voltage.

Specifically, as the writing time becomes longer, the threshold voltage will gradually increase. The most efficient operating voltage of non-volatile memory cell changes when the threshold voltage changes. When the threshold voltage of the non-volatile memory cell is approximately 1 volt, the first word voltage is the low voltage and the first common-source voltage is the middle voltage in the writing activity, thereby reducing the power required by the load. When the writing activity is endlessly performed, the threshold voltage will gradually change to 1.5 volts. At this time, the operating efficiency of the memory cell will gradually deteriorate. Therefore, the first word voltage is the middle voltage and the first common-source voltage is the low voltage, so that the memory cell maintains better operating efficiency. Similarly, when the threshold voltage is approximately 2 volts, the first word voltage is the high voltage and the first common-source voltage is the grounding voltage, thereby improving the overall writing efficiency and shortening the writing time.

As the erasing time becomes longer, the threshold voltage gradually decreases. When the non-volatile memory cell has a high threshold voltage, such as 2 volts, the channel lacks electron flow, which is disadvantageous to the generation of hot holes in the erasing activity. The first word voltage is the low voltage, so that a small current will pass through the channel, thereby allowing the memory cell to easily perform the erasing activity. When the erasing activity is endlessly performed, the threshold voltage gradually decreases, such as changing to 1.5 volts. At this time, the memory cell already has enough electron flow. However, too much electron flow will deteriorate the operating efficiency. Therefore, the first word voltage is set to the grounding voltage to allow the memory cell to maintain better operating efficiency and shorten the erasing time.

When the operable memory cell does not perform the writing activity or the erasing activity, the bit line BL coupled to the operable memory cell is electrically floating, a second word voltage and a second common-source voltage are respectively applied to the first word line WL1 and the first common-source line SL1, the second word voltage is the grounding voltage or the low voltage, and the second common-source voltage is the middle voltage. The first word line WL1 is coupled to the grounding voltage or the low voltage based on process characteristics.

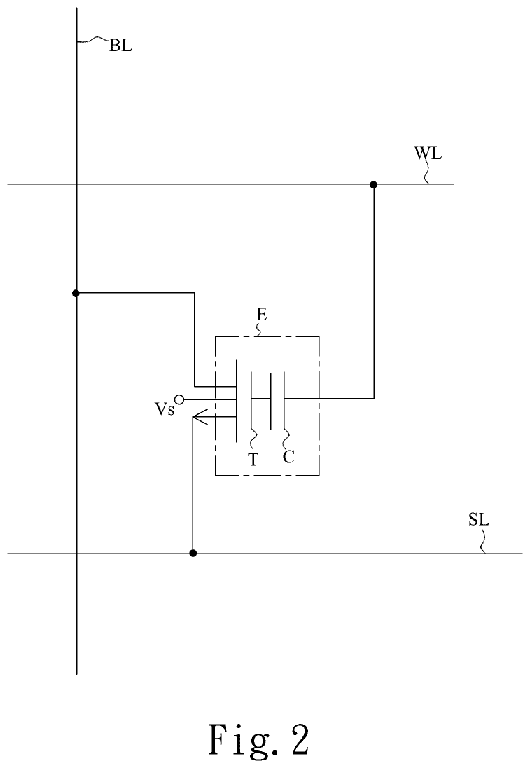

FIG. 2 is a schematic diagram illustrating a non-volatile memory cell according to an embodiment of the present invention. Referring to FIG. 2, a method for operating a non-volatile memory cell E is introduced as follows. The non-volatile memory cell E, coupled to a word line WL, a bit line BL, and a common-source line SL, includes an N-type field-effect transistor (FET) T and a capacitor C. The gate of the N-type FET T is coupled to the word line WL through the capacitor C. The drain of the N-type FET T is coupled to the bit line BL. The source of the N-type FET T is coupled to the common-source line SL.

In the method for operating a non-volatile memory cell E, a grounding voltage as a body voltage Vs is applied to the body of the N-type FET T of the non-volatile memory cell E. The body is implemented with a P-type well, a P-type semiconductor substrate, or a P-type epitaxial layer. When the non-volatile memory cell E performs a writing activity or an erasing activity, a bit voltage, a first word voltage, and a first common-source voltage are respectively applied to the bit line BL, the word line WL, and the common-source line SL. The N-type FET T of the non-volatile memory cell E has a threshold voltage. In the writing activity, the bit voltage is equal to a high voltage, the first word voltage increases incrementally and serves as a step voltage in response to the threshold voltage that increases incrementally, and the first common-source voltage decreases incrementally and serves as a step voltage in response to the threshold voltage that increases incrementally. In the erasing activity, the bit voltage is equal to the high voltage, the first word voltage decreases incrementally and serves as a step voltage in response to the threshold voltage that decreases incrementally, and the first common-source voltage is equal to the grounding voltage. The high voltage is equal to the drain-to-source breakdown voltage of the N-type FET T minus the threshold voltage. The grounding voltage is zero voltage.

For example, in the writing activity, the first word voltage is a low voltage, a middle voltage, or the high voltage, the first common-source voltage is the middle voltage, the low voltage, or the grounding voltage, the high voltage is greater than the middle voltage, the middle voltage is greater than the low voltage, and the low voltage is greater than the grounding voltage. The middle voltage may be equal to the drain-to-source breakdown voltage of the N-type FET T×0.5. The low voltage may be equal to the drain-to-source breakdown voltage of the N-type FET T×0.25. In the erasing activity, the first word voltage is the low voltage or the grounding voltage.

When the non-volatile memory cell E does not perform the writing activity or the erasing activity, the bit line BL is electrically floating, a second word voltage and a second common-source voltage are respectively applied to the word line WL and the common-source line SL, the second word voltage is the grounding voltage or the low voltage, and the second common-source voltage is the middle voltage. The word line WL is coupled to the grounding voltage or the low voltage based on process characteristics.

According to the embodiments provided above, the methods for operating a non-volatile memory array and a non-volatile memory cell apply step voltages to the word line and the common-source line in the writing activity and apply a step voltage to the word line in the erasing activity to shorten the time of the writing activity or the erasing activity, thereby improving the writing efficiency or the erasing efficiency.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A method for operating a non-volatile memory array that comprises a plurality of common-source lines arranged in parallel, a plurality of word lines arranged in parallel, a plurality of bit lines arranged in parallel, and a plurality of sub-memory arrays, the plurality of common-source lines comprise a first common-source line, the plurality of common-source lines are parallel to the plurality of word lines, the plurality of word lines comprise a first word line, the plurality of word lines are perpendicular to the plurality of bit lines, the plurality of bit lines comprise a first bit line, a second bit line, a third bit line, and a fourth bit line, each of the plurality of sub-memory arrays is coupled to one of the plurality of common-source lines, one of the plurality of word lines, and four of the plurality of bit lines, each of the plurality of sub-memory arrays comprises a first non-volatile memory cell, a second non-volatile memory cell, a third non-volatile memory cell, and a fourth non-volatile memory cell, the first non-volatile memory cell is coupled to the first word line, the first bit line, and the first common-source line, the second non-volatile memory cell is coupled to the first word line, the second bit line, and the first common-source line, the third non-volatile memory cell is coupled to the first word line, the third bit line, and the first common-source line, the fourth non-volatile memory cell is coupled to the first word line, the fourth bit line, and the first common-source line, each of the first non-volatile memory cell, the second non-volatile memory cell, the third non-volatile memory cell, and the fourth non-volatile memory cell comprises an N-type field-effect transistor (FET), the first non-volatile memory cell, the second non-volatile memory cell, the third non-volatile memory cell, or the fourth non-volatile memory cell is used as an operable memory cell, and the method comprises:
applying a grounding voltage to a body of the N-type FET of the operable memory cell; and
when the operable memory cell performs a writing activity or an erasing activity, respectively applying a bit voltage, a first word voltage, and a first common-source voltage to the bit line, the first word line, and the first common-source line that are coupled to the operable memory cell;
wherein the N-type FET of the operable memory cell has a threshold voltage;
wherein in the writing activity, the bit voltage is equal to a high voltage, the first word voltage increases incrementally in response to the threshold voltage that increases incrementally, and the first common-source voltage decreases incrementally in response to the threshold voltage that increases incrementally;
wherein in the erasing activity, the bit voltage is equal to the high voltage, the first word voltage decreases incrementally in response to the threshold voltage that decreases incrementally, and the first common-source voltage is equal to the grounding voltage;
wherein the high voltage is equal to a drain-to-source breakdown voltage of the N-type FET of the operable memory cell minus the threshold voltage.

2. The method for operating the non-volatile memory array according to claim 1, wherein in the writing activity, the first word voltage is a low voltage, a middle voltage, or the high voltage, the first common-source voltage is the middle voltage, the low voltage, or the grounding voltage, the high voltage is greater than the middle voltage, the middle voltage is greater than the low voltage, and the low voltage is greater than the grounding voltage.

3. The method for operating the non-volatile memory array according to claim 1, wherein in the erasing activity, the first word voltage is a low voltage or the grounding voltage, the high voltage is greater than the low voltage, and the low voltage is greater than the grounding voltage.

4. The method for operating the non-volatile memory array according to claim 1, wherein when the operable memory cell does not perform the writing activity or the erasing activity, the bit line coupled to the operable memory cell is electrically floating, a second word voltage and a second common-source voltage are respectively applied to the first word line and the first common-source line, the second word voltage is the grounding voltage or a low voltage, the second common-source voltage is a middle voltage, the high voltage is greater than the middle voltage, the middle voltage is greater than the low voltage, and the low voltage is greater than the grounding voltage.

5. The method for operating the non-volatile memory array according to claim 1, wherein the body is implemented with a P-type well, a P-type semiconductor substrate, or a P-type epitaxial layer.

6. A method for operating a non-volatile memory cell that is coupled to a word line, a bit line, and a common-source line, the non-volatile memory cell comprises an N-type field-effect transistor (FET), and the method comprises:
applying a grounding voltage to a body of the N-type FET of the non-volatile memory cell; and
when the non-volatile memory cell performs a writing activity or an erasing activity, respectively applying a bit voltage, a first word voltage, and a first common-source voltage to the bit line, the word line, and the common-source line;
wherein the N-type FET of the non-volatile memory cell has a threshold voltage;
wherein in the writing activity, the bit voltage is equal to a high voltage, the first word voltage increases incrementally in response to the threshold voltage that increases incrementally, and the first common-source voltage decreases incrementally in response to the threshold voltage that increases incrementally;
wherein in the erasing activity, the bit voltage is equal to the high voltage, the first word voltage decreases incrementally in response to the threshold voltage that decreases incrementally, and the first common-source voltage is equal to the grounding voltage;
wherein the high voltage is equal to a drain-to-source breakdown voltage of the N-type FET of the non-volatile memory cell minus the threshold voltage.

7. The method for operating the non-volatile memory cell according to claim 6, wherein in the writing activity, the first word voltage is a low voltage, a middle voltage, or the high voltage, the first common-source voltage is the middle voltage, the low voltage, or the grounding voltage, the high voltage is greater than the middle voltage, the middle voltage is greater than the low voltage, and the low voltage is greater than the grounding voltage.

8. The method for operating the non-volatile memory cell according to claim 6, wherein in the erasing activity, the first word voltage is a low voltage or the grounding voltage, the high voltage is greater than the low voltage, and the low voltage is greater than the grounding voltage.

9. The method for operating the non-volatile memory cell according to claim 6, wherein when the non-volatile memory cell does not perform the writing activity or the erasing activity, the bit line is electrically floating, a second word voltage and a second common-source voltage are respectively applied to the word line and the common-source line, the second word voltage is the grounding voltage or a low voltage, the second common-source voltage is a middle voltage, the high voltage is greater than the middle voltage, the middle voltage is greater than the low voltage, and the low voltage is greater than the grounding voltage.

10. The method for operating the non-volatile memory cell according to claim 6, wherein the body is implemented with a P-type well, a P-type semiconductor substrate, or a P-type epitaxial layer.
